(19) United States
(12) Patent Application Publication
(10) Pub. No.: US 2006/0197407 A1
(43) Pub. Date: Sep. 7, 2006

(54) Construction of saw devices

(76) Inventors: David Daniel George Vile, Bicester (GB); Graham Michael Freakes, Aldcliffe (GB); Raymond David Lohr, Long Crendon (GB); Mark Lee, Totton (GB); Arthur John Leigh, Banbury (GB)

Correspondence Address: KEUSEY, TUTUNJIAN & BITETTO, P.C., 20 CROSSWAYS PARK NORTH, SUITE 210, WOODBURY, NY, 11797, US

(21) Appl. No.: 10/547,913

(22) PCT Filed: Mar. 5, 2004
(86) PCT No.: PCT/GB04/00940

§ 371 Date: Sep. 8, 2005

(30) Foreign Application Priority Data
Mar. 10, 2003 (GB) 0305461.6

(51) Int. Cl. H04R 17/00; H01L 41/00

(52) U.S. Cl. 310/313 R; 451/41; 29/846; 29/25.35

(57) ABSTRACT

A silicon or quartz wafer for forming a SAW device is the subject of grinding and lapping operation to form its basic shape. The opposing surfaces, as well as the edges extending therebetween, are the polished to reduce the number and size of defects in the surfaces. Metal is deposited onto one of the opposing surfaces which, in use, will be under compression, to form electronic components thereon, and a multi-metallic coating having an outer layer formed of gold is applied to the other surface to form a solder pad by means of which the wafer may be fastened to a shaft or the like by soldering. Martensitic stainless steel is used as a mount, saddle or housing for the SAW substrate.

### BACKGROUND OF THE INVENTION

1. Field of the Invention

The present invention relates to improvements in the construction of quartz and silicon SAW substrates such as SAW (Surface Acoustic Wave) devices, and in particular to improvements in the surface finishing and packaging of such devices.

2. The Prior Art

The ultimate tensile bending strength of a brittle material depends not only on its size and stiffness but also on the presence of pre-existing defects. When a quartz SAW substrate, such as a SAW device, is subjected to bending, for example simple 3-point bending, the surface on the outside of the bend is placed in tension whilst the surface on the inside of the bend is placed in compression. Any pre-existing defect while exists in the surface under tension will, then, be an area of weakness and hence likely be the initial source of any failure of the component under bending. The failure strength under bending will, therefore, be limited by the size of the largest pre-existing defect in the component.

Conventionally, quartz SAW substrates are produced by grinding and lapping operations, which results in a large number of small defects on the surfaces thereof whose size is characteristic of the grinding and lapping processes. The compressed surface of the component is then finished by polishing so as to facilitate deposition of metal thereto to form the various components of the SAW device. Traditionally, however, the tensioned surface has not been so finished for two reasons: firstly, because the extra costs involved in polishing both surfaces of the component was deemed unnecessary and secondly, because the unpolished surface was found to suppress reflection of the bulk wave during operation of the SAW device, thereby reducing parasitic losses which result from those reflections.

### SUMMARY OF THE INVENTION

According to one aspect of the invention there is provided a method of finishing SAW substrates by polishing opposing surfaces thereof.

According to another aspect of the invention there is provided a metallization layer on a surface of the SAW substrate which serves as a soldering pad.

The invention further includes SAW substrates manufactured according to the above noted methods.

According to a further aspect of the invention there is provided AuSn solder for soldering the SAW substrate to a structural member.

In another aspect of the invention the SAW substrate is bonded to a structural component using a glass frit.

According to a further aspect of the invention a martensitic stainless steel mount is coupled to the SAW substrate.

### DETAILED DESCRIPTION OF THE PREFERRED EMBODIMENTS

According to one aspect of the present invention there is provided a method of production of SAW substrates, such as quartz or silicon components wherein following grinding and lapping operations, opposing surfaces of the component are polished so as to reduce the number and of size of the defects in the surface.

The present invention further provides a SAW device composed of a quartz SAW substrate having a first surface upon which metal is deposited to form components of the SAW device and which, upon bending of the device during use, will be under compression, and a second surface opposite said first which, upon bending of the device in use, will be tensioned, both said first and second surfaces being polished.

The present invention offers the advantage that a very significant increase in the bending strength of the SAW device is achieved. Further improvements may advantageously be achieved by also polishing the edges of the SAW device in order to eliminate any stress raisers resulting from the cutting of the device from the wafer.

In some applications, components such as SAW devices are attached directly to test apparatus, such as a shaft, rather than being housed in a case or the like which is then suitably fastened in place on the test apparatus. Such components may be glued in place by using conventional adhesives, but the mechanical properties of the resulting bond have been found to reduce the responsiveness and sensitivity of SAW devices. Instead, therefore, it has been found to be advantageous to fasten such a SAW device by high temperature soldering, which may be achieved by providing a metallization layer on the bonding surface of the substrate of the device. Soldering has the advantage of greatly improving the transfer of strain and thermal properties of the transducer and hence improves the accuracy and sensitivity of a SAW device.

The present invention further teaches the provision of a metallization layer on the surface of a component such as a planar quartz component, the metallization layer being formed of a multi-metallic coating having an outer layer formed of gold, as well as a method of fastening such a planar quartz component such as a SAW device, to a structural component such as a shaft by means of soldering using AuSn eutectic composition solder.

This has the advantage of bonding well to the metallized layer, particularly if a multi-metallic coating is applied to the bonding surface of the SAW device with the outer coating thereof being gold, and couples the SAW device particularly effectively to the stress field of the structural component which it is intended to measure due to the high stiffness (E approximately 68 GPa), tensile strength (approximately 275 MPa) and melting point (approximately 280° C.) of AuSn enabling it to act as a good strain transfer medium.

Unlike conventional polymeric backed foil strain gauges, single crystal quartz is a stiff material (E approximately 80 GPa), and the stress levels required successfully to transmit strain from a structural member formed of, for example, steel, to a quartz SAW device are necessarily high. As a result creep will manifest itself at much lower temperatures if a conventional strain gauge adhesive, such as a conventional polymeric strain gauge adhesive, is used. The use of AuSn, in contrast, results in much lower levels of creep and hysteresis at the high temperatures, which can be up to 125 degrees centigrade, typically encountered in automotive applications.

AuSn also has the benefit of high thermal conductivity, thereby minimizing thermally induced strain gradients, and hence further improving accuracy of the device.

Instead of soldering, the SAW substrate may instead be bonded directly to a structural member using glass frit, such as 80% silver and 20% glass, preferably at a temperature in the range of 400-450° C. In this way no metallization layer is required.

In other applications, quartz and silicon components such as SAW devices are housed in or mounted on a separate structure such as a box, a saddle or the like, which separate structure is then fastened to a structural component or within a test environment The performance (repeatability, linearity, hysteresis and creep) of a sensor incorporating a SAW or similar device will, in such cases, then depend on maintaining not only all the component parts of the device itself within their elastic range for all operating conditions, but also the components of the structure in which the device is enclosed or mounted, such as the lid and base of a case, in their elastic range during operation.

Conventionally, silicon and quartz devices for electronic applications, are packaged in materials such as austenitic stainless steel, kovar or even plated mild steel, and these materials work well for applications where the device is essentially decoupled from the environment, since they can easily be formed and provide an effective bather against corrosion etc. However, these materials do not have a high elastic limit and are likely to give rise to non-linear behavior in applications where the device must be coupled to the environment for its operation, such as tire pressure sensing applications of SAW devices.

In accordance with a further aspect of the present invention, then, silicon and quartz devices for electronic applications are, instead, packaged in or mounted on martensitic stainless steels, in particular precipitation hardened martensitic stainless steels. Such materials have the advantage that they have high elastic limits which promote good sensor performance while still providing protection against corrosion. 17-7PH and 17-4PH stainless steel have been found to provide particularly effective results.

The various references herein to SAW substrates include but are not limited to sensors based on a high-Q resonant structure or several structures sensitive to physical quantities such as mechanical strain, temperature, moisture etc., for exampled SAW (Surface Acoustic Wave) resonators, STW (Surface Transverse Wave) resonators, FBAR thin film bulk acoustic wave resonators, dielectric resonators etc.

1-16. (canceled)

17. An apparatus comprising a packaging for a SAW substrate at least partially formed of martensitic stainless steel.

18. The packaging according to claim 17, wherein said stainless steel is hardened.

19. The packaging according to claim 17, wherein said stainless steel is 17-7PH or 17-4PH stainless steel.

20. The packaging according to claim 17, wherein the packaging includes a first section on which, in use, the SAW substrate is carried, which is formed of said martensitic stainless steel.

21. The packaging according to claim 17, having a chamber formed therein for receiving a SAW device.

22. A device for protecting a substrate in a non-environmentally-isolating package, comprising:
a sensor including a SAW substrate; and
a martensitic stainless steel mount coupled to said SAW substrate,
wherein said martensitic stainless steel mount possesses a high elastic range so that said sensor is able to monitor the environment through said mount.

23. The device according to claim 22, wherein said martensitic stainless steel mount includes precipitation hardened martensitic stainless steel.

24. The device according to claim 22, wherein the matensitic stainless steel is selected from the group consisting of 17-7PH stainless steel and 17-4PH stainless steel.

25. The device according to claim 22, wherein said martensitic stainless steel mount comprises a saddle for fastening the sensor to a structural component.

26. The device according to claim 22, wherein said martensitic stainless steel mount comprises a housing that encloses said sensor.
